(19) United States
(12) Patent Application Publication
(10) Pub. No.: US 2005/0199745 A1
(43) Pub. Date: Sep. 15, 2005

(54) Method of assembling a fuel injector

(76) Inventor: Jean-Francois Berlemont, Brussels (BE)

Correspondence Address: DELPHI TECHNOLOGIES, INC., M/C 480-410-202, PO BOX 5052, TROY, MI, 48007, US

(21) Appl. No.: 11/076,144

(22) Filed: Mar. 8, 2005

(30) Foreign Application Priority Data
Mar. 11, 2004 (EP) 04251419.0

(51) Int. Cl. B05B 1/08; H02N 2/00; H01L 41/08; F02M 61/20

(52) U.S. Cl. 239/88; 239/102.2; 239/533.9; 310/328

(57) ABSTRACT

A method of assembling a fuel injector (8) comprising a fuel injector body having an accumulator volume (22) defined therein is described. The method comprises: providing an encapsulated actuator arrangement (29a) having a piezoelectric actuator stack (29) and electrical connector means (34,36), wherein the stack (29) is encapsulated in a sleeve member (30); providing a volume of sealing material (42) in the region of the electrical connector means (34,36); locating the encapsulated actuator arrangement (29a) in the accumulator volume (22); applying heat indirectly to the volume of sealing material (42) so as to soften the volume of sealing material; and applying pressure to the encapsulated actuator arrangement (29a) such that the volume of sealing material (42) deforms to form a substantially fluid-tight seal (38) between the encapsulated actuator arrangement (29a) and the accumulator volume (22) in the region of the electrical connector means (34,36).

### TECHNICAL FIELD

The present invention relates to a method of assembling a fuel injector for use in a fuel system of an internal combustion engine, particularly a fuel system of the accumulator or common rail type, the fuel injector being of the type controlled using a piezoelectric actuator.

### BACKGROUND ART

In a known piezoelectrically actuated fuel injector, a piezoelectric actuator arrangement is operable to control the position occupied by a control piston, the piston being moveable to control the fuel pressure within a control chamber defined, in part, by a surface associated with the injector valve needle to control movement of the needle. The piezoelectric actuator typically includes a stack of piezoelectric elements, the axial length of which is controlled by applying a voltage across the stack through an electrical connector. It is known to arrange the piezoelectric stack within an accumulator volume which is arranged to receive high pressure fuel, in use, so as to apply a hydrostatic load to the piezoelectric stack. A fuel injector of this type is described in the Applicant's granted European patent no. 0 995 901.

As the accumulator volume receives fuel at high pressure, it is therefore important that the piezoelectric stack is substantially sealed from fuel within the accumulator volume. For this purpose, it is known to use a plastic over-moulding technique to encapsulate the piezoelectric stack within a plastic casing, or a sleeve member as described in the Applicant's co-pending published International patent application WO 02/061856. A further requirement is that the encapsulated piezoelectric stack forms a good seal with the top of the accumulator volume in the region of the electrical connector to prevent leakage of fuel thereto from the accumulator volume. Any such leakage of fuel will of course affect the integrity of the electrical connection and thus adversely affect the performance of the fuel injector.

It is known that a seal may be provided between an encapsulated actuator arrangement and the top of the accumulator volume, the seal being pre-formed to give a slight interference fit between these components. In this case, a sealing force is provided by pressurisation forces which deform the seal into position. This arrangement is not ideal, as it does not take into account variations in the sizes of components which occur during the manufacture thereof.

It is also important to ensure that any seal which is provided does not significantly increase the size of the actuator arrangement as the accommodation space available for the actuator arrangement within the fuel injector is limited.

It is an object of the present invention to provide a method of assembling a fuel injector which alleviates the above mentioned problems.

### SUMMARY OF THE INVENTION

According to a first aspect of the present invention there is provided a method of assembling a fuel injector comprising a fuel injector body having an accumulator volume defined therein, the method comprising: providing an encapsulated actuator arrangement having a piezoelectric actuator stack and electrical connector means, wherein the stack is encapsulated in a sleeve member; providing a volume of sealing material in the region of the electrical connector means; locating the encapsulated actuator arrangement in the accumulator volume; applying heat indirectly to the volume of sealing material so as to soften the volume of sealing material; and applying pressure to the encapsulated actuator arrangement such that the volume of sealing material deforms to form a substantially fluid-tight seal between the encapsulated actuator arrangement and the accumulator volume in the region of the electrical connector means.

By applying heat indirectly, it is meant that heat is not applied to the volume of sealing material directly, but that the heat is applied through the fuel injector body itself.

Each substantially fluid-tight seal which is formed in accordance with the present invention is individual to each particular fuel injector, thereby compensating for slight misalignments and manufacturing inaccuracies of the fuel injector components. Thus, fuel is less likely to leak from the accumulator volume to the electrical connector means as a result of imperfections which may arise in a pre-formed seal.

In one embodiment of the present invention, the volume of sealing material is preferably integrally formed with the sleeve member, and the sealing material and the sleeve member are preferably formed from the same material. Preferably the volume of sealing material and the sleeve member comprise a thermoplastic material. Most preferably the thermoplastic material comprises poly ethyl ether ketone (PEEK), polyphenylene sulphide (PPS), liquid crystal polymer (LCP), a fluoropolymer, or any other suitable thermoplastic material which does not degrade on melting and can be remelted. Alternatively, the sealing material and/or the sleeve member may comprise an ultraviolet (uv) curable material.

In another embodiment of the present invention, the method comprises the further step of applying the volume of sealing material to the encapsulated actuator arrangement prior to the locating step. Thus, the volume of sealing material and the sleeve member may be formed from the same material, or from different materials.

The locating step may further comprise inserting a pre-formed seal member between the encapsulated actuator arrangement and the accumulator volume in the region of the electrical connector means. The volume of sealing material may then be applied to the encapsulated actuator arrangement and/or to the pre-formed seal member.

Preferably the electrical connector means has a stepped profile defining a shoulder and a neck receivable by a passageway provided at a ceiling end of the accumulator volume, and wherein, during the step of applying pressure, the volume of sealing material deforms to form a substantially fluid-tight seal between at least a portion of the shoulder of the electrical connector means and the ceiling end of the accumulator volume, and/or between at least a portion of the neck of the electrical connector means and the passageway.

Conveniently, the method of the present invention may comprise the further step of preparing at least portion of the accumulator volume and/or the encapsulated actuator arrangement so as to improve the adherence of the sealing material thereto. The preparation step may comprise roughening by sandblasting or etching, for example. Alternatively, the preparation step may comprise cleaning, or applying a chemical adhesion promoter.

Preferably, the step of applying heat indirectly to the volume of sealing material is carried out via, for example, induction heating. Alternatively, if the volume of sealing material is uv curable, then heat may be applied via ultraviolet radiation.

Pressure may be applied to the encapsulated actuator arrangement via hydrostatic loading. That is, by the application of a pressurised fluid such as nitrogen, or diesel oil, for instance. Alternatively, pressure may be applied to the encapsulated actuator arrangement using a pneumatic or mechanic tool, or a hydraulic press, for example. Pressure is conveniently applied to the end of the encapsulated actuator arrangement opposite the electrical connector means.

According to a second aspect of the present invention there is provided a fuel injector assembled according to the aforedescribed method.

The fuel injector may comprise a fuel injector body having: a) an accumulator volume defined therein; b) an encapsulated actuator arrangement comprising a piezoelectric actuator stack encapsulated in a sleeve member, the piezoelectric actuator stack further comprising an electrical connector means having a stepped profile defining a shoulder and a neck which extends into a passageway defined in the fuel injector body and which is connectable to an external electrical connector; and c) a fluid tight seal provided between at least a portion of the shoulder of the electrical connector means and a ceiling end of the accumulator volume and/or between at least a portion of the neck of the electrical connector means and the passageway.

### BRIEF DESCRIPTION OF DRAWINGS

Preferred embodiments of the present invention will be described, by way example only, with reference to the accompanying drawings, in which:

FIG. 1 is a sectional view illustrating a known piezoelectric fuel injector which may be assembled according to the present invention;

FIG. 2 is an enlarged view illustrating part of the fuel injector of FIG. 1;

FIG. 3 is another enlarged view illustrating a part of the fuel injector of FIG. 1; and

FIGS. 4a, 4b and 4c illustrate the steps involved in assembling a piezoelectric fuel injector, according to one embodiment of the present invention.

### DETAILED DESCRIPTION OF THE PREFERRED EMBODIMENTS

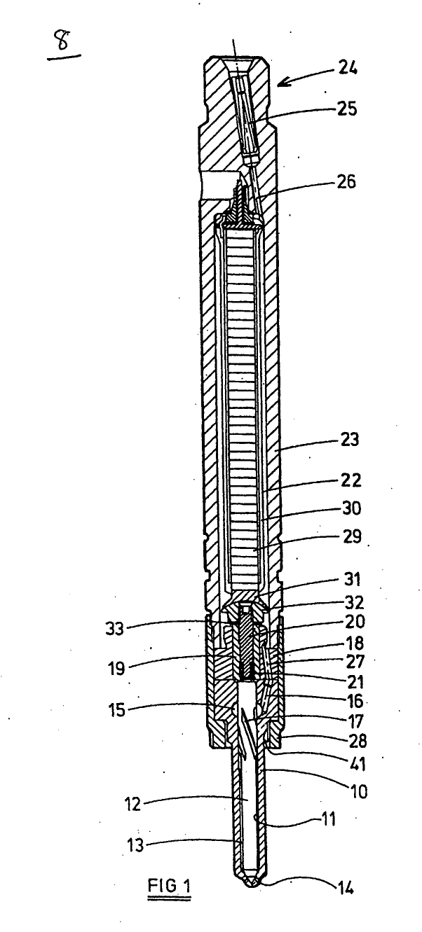

Referring to FIG. 1, there is shown a known piezoelectric fuel injector 8 which may be assembled in a number of ways. The components of the fuel injector 8 will firstly be described, followed by a method of assembling such a fuel injector according to the present invention.

The fuel injector 8 illustrated in FIG. 1 comprises a nozzle body 10 provided with a blind bore 11 within which a valve needle 12 is reciprocable. The valve needle 12 is shaped for engagement with a seating defined adjacent the blind end of the bore 11. The needle 12 is of stepped form, including a relatively large diameter region which is of diameter substantially equal to that of the adjacent part of the bore 11 and arranged to guide the needle 12 for sliding movement within the bore 11, and a reduced diameter portion which defines, with the bore 11, a delivery chamber 13. It will be appreciated that engagement of the needle 12 with the seating controls communication between the delivery chamber 13 and one or more outlet openings 14 located downstream of the seating.

The bore 11 is shaped to define an annular gallery 15 which communicates with a drilling 16 provided in the nozzle body. The needle 12 is provided with flutes 17 defining flow paths between the annular gallery 15 and the delivery chamber 13. The needle 12 defines an angled step at the interconnection of the relatively large and smaller diameter regions thereof, the step forming a thrust surface which is exposed to the fuel pressure within the delivery chamber 13 such that when fuel under high pressure is applied to the delivery chamber 13, the action of the fuel applies a force to the needle 12 urging the needle away from its seating. The exposed end surface of the needle 12 similarly forms a thrust surface against which fuel under pressure may act to urge the needle towards its seating.

The nozzle body 10 abuts a distance piece 18 provided with a through bore within which is piston member 19 of tubular form is slidable. A screw-threaded rod 20 is engaged with the passage defined by the tubular piston member, a spring 21 being engaged between the screw-threaded rod 20 and the end surface of the valve needle 12. The spring applies a biasing force to the needle 12, urging the needle towards its seating.

The end surface of the needle 12 engages a spring 21, and is exposed to the fuel pressure within a control chamber 40 defined between the nozzle body 10, the distance piece 18, the piston member 19 and a screw-threaded rod 20. The fuel pressure within the control chamber 40 assists the spring 21 in applying a force to the needle 12 urging the needle towards its seating.

The distance piece 18 abuts an end of an actuator housing 23 which is of elongate form and is provided with a bore defining an accumulator volume 22. The accumulator volume 22 includes a lower region, which extends to the distance piece 18, and a ceiling end 22a. The actuator housing 23 is provided with an inlet region 24 arranged to be coupled to a high pressure line (not shown) to permit connection of the fuel injector 8 to a source of fuel under high pressure, for example a common rail charged to an appropriate high pressure by a suitable high pressure fuel pump. The inlet region 24 houses an edge filter member 25 to remove particulate contaminants from the flow of fuel to the injector 8, in use, thereby reducing risk of damage to the various components of the injector. The clean side of the filter formed by the edge filter member 25 communicates through a drilling 26 with the accumulator 22. A drilling 27 provided in the distance piece 18 permits communication between the accumulator volume 22 and the drilling 16 provided in the nozzle body 10. A cap nut 28 is used to secure the nozzle body 10 and distance piece 18 to the actuator housing 23.

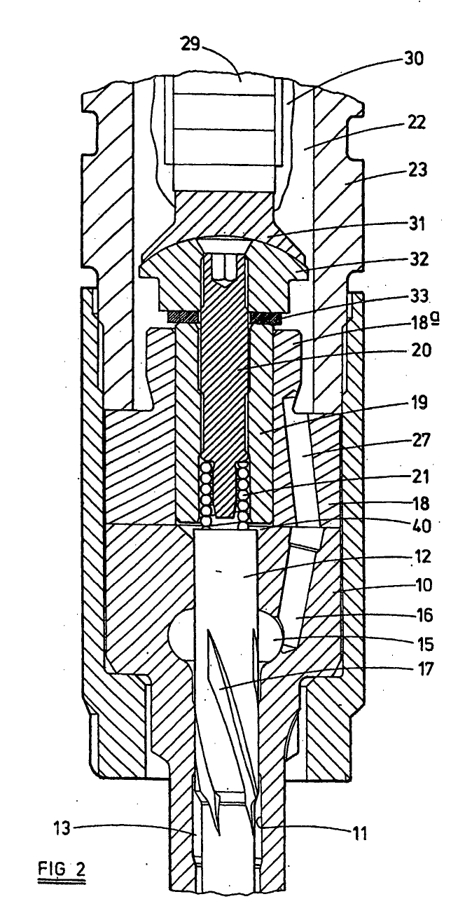

Additionally, as illustrated in FIG. 2, the distance piece 18 is shaped to include a region 18a of reduced diameter which extends into the accumulator volume 22. High pressure fuel within the accumulator volume 22 acts upon the outer surface of this region 18a of the distance piece thereby applying a radial compressive load thereto, which reduces leakage of fuel between the piston member 19 and the distance piece 18, in use.

A piezoelectric actuator stack 29 is located within the accumulator volume 22. The actuator stack 29 may be provided with a coating 30 of flexible sealant material, the sealant material being of an electronics conformal nature. The coating 30 acts to prevent or restrict the ingress of fuel into the joints between the individual elements forming the piezoelectric actuator stack 29, thus reducing the risk of damage to the actuator stack 29. The actuator stack 29 carries, at its lower end, an anvil member 31 which is shaped to define a part-spherical recess. A load transmitting member 32 including a region of part-spherical form extends into the part-spherical recess of the anvil member 31. The load transmitting member 32 is provided with an axially extending, screw-threaded passage within which the screw-threaded rod engages. A spacer or shim 33 is located between the load transmitting member 32 and the adjacent face of the tubular piston member 19 to control the spacing of these components.

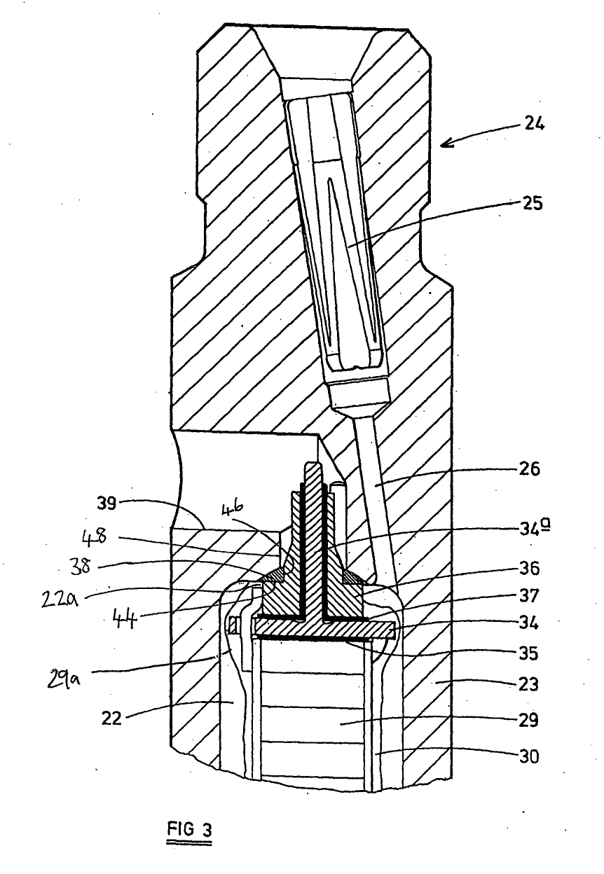

Referring now to FIG. 3, the upper end of the accumulator stack 29 is secured to a first terminal member 34 using an appropriate adhesive, an insulating spacer member 35 being located between the first terminal member 34 and the end surface of the actuator stack 29.

A second, outer terminal member 36 surrounds a stem 34a of the first terminal member, another insulator member 37 being located between the first and second terminal members 34, 36. The second terminal member 36 has a stepped profile with a shoulder portion 44 and a neck 46. The shoulder portion 44 defines an abutment for a seal member 38, with a suitable adhesive being used to secure these integers to one another.

The first and second terminals 34,36 form an electrical connector means, and extend through a longitudinal drilling 48 which opens into the accumulator volume 22. A radial drilling 39 is provided in the actuator housing 23 to communicate with the drilling 48, so as to permit an appropriate electrical connection to be made, via the electrical connector means, to permit control of the piezoelectric actuator.

The fuel pressure within the accumulator volume 22 assists the adhesive in retaining the various components in position. The combination of the piezoelectric stack 29 which is encapsulated in the sleeve member 30, and the electrical connector means 34,36 is hereinafter referred to as an encapsulated actuator arrangement 29a.

The seal member 38 sits on the shoulder portion 44 of the second terminal member 36 and engages around part of the neck 46 thereof. The seal member 38 may include a pre-formed seal member which has a surface of part-spherical or part-spheroid form which is arranged to seat within a correspondingly shaped recess formed around the longitudinal drilling 48 which opens into the ceiling end 22a of the accumulator volume 22. The pre-formed seal member may be constructed from a high performance engineering thermoplastics material such as PEEK, PPS or LCP, or may be constructed from a ceramic material.

Details of how the fuel injector 8 operates is described fully in EP 0 995 901, and so will not be discussed further here.

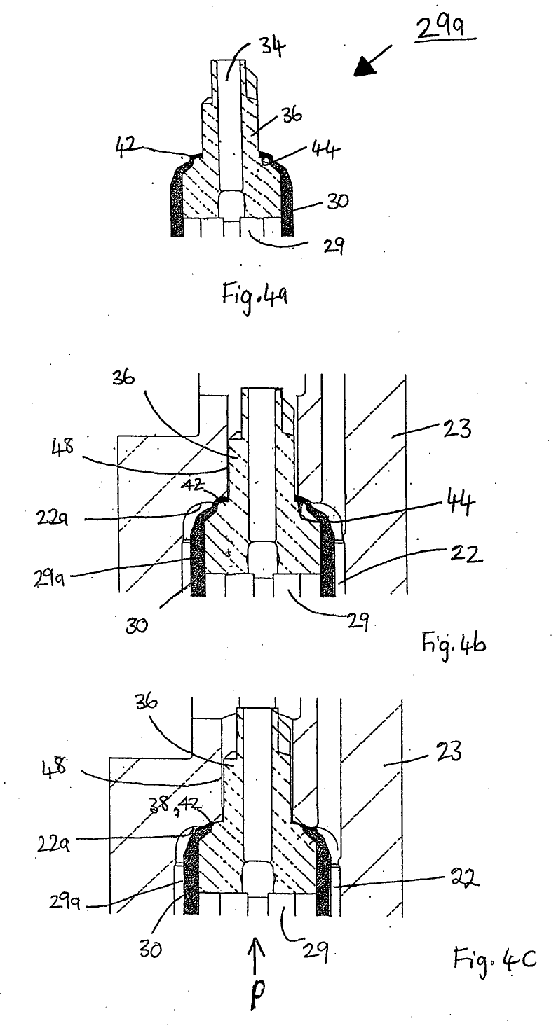

A method of assembling the fuel injector 8 so that a fluid tight seal is formed between the encapsulated actuator arrangement 29a and the accumulator volume 22 will now be described, according to a first embodiment of the present invention, with reference to FIGS. 4a to 4c. FIG. 4a illustrates the upper portion of the encapsulated actuator arrangement 29a of FIGS. 1 to 3, where the upper part of the piezoelectric stack 29 is just visible. FIGS. 4b and 4c illustrate upper portions of the encapsulated actuator arrangement 29a of FIGS. 1 to 3, wherein these portions are disposed within the corresponding parts of the actuator housing 23.

Firstly, a pre-assembled encapsulated actuator arrangement 29a is provided, as shown in FIG. 4a. Typically, the sleeve member 30 of the encapsulated actuator arrangement 29a is formed from a thermoplastic material. An additional volume of sealing material 42, such as a thermoplastic material, is applied to the shoulder portion 44 of the second terminal member 36. If the sealing material is of a different composition to that of the sleeve member 30, or simply to further improve the sealing function of the seal member 38, then it may be necessary to adequately prepare the surfaces to be bonded. For example the surfaces may be cleaned to ensure that they are free from contamination, or a chemical adhesion promoter can be used to improve adhesion. Alternatively, the surfaces may be roughened to increase the effective surface area of the surfaces. The surfaces of the ceiling end 22a of the accumulator volume 22, the wall of the longitudinal drilling 48, and the upper part of the encapsulated actuator arrangement 29a could be prepared in this manner, the preparation step being carried out prior to the assembly of the fuel injector 8 and the seal member 38 formed in the steps described above.

The pre-assembled actuator arrangement 29a of FIG. 4a is then introduced into the accumulator volume 22 such that the shoulder portion 44 of the second terminal member 36 sits adjacent the ceiling end 22a of the accumulator volume 22. The neck of the second terminal member 36 (and part of the stem 34a of the first terminal member 34) are received within the longitudinal drilling 48. This is shown in FIG. 4b. Heat is then locally, and indirectly, applied to the volume of sealing material 42. More specifically, heat is indirectly applied to the region of the interface of the ceiling end 22a of the accumulator volume 22 and the upper part of the encapsulated actuator arrangement 29a such that the volume of sealing material 42 in this region is softened.

The method by which heat is applied to soften the volume of sealing material 42 depends on the composition of the sealing material used. Considering the present example, where a thermoplastic material is utilised, a method such as induction heating may be employed.

In induction heating, an induction coil which is connected to an alternating current power supply is provided (not shown). The power supply sends an alternating current through the induction coil thereby generating a magnetic field. When the assembled fuel injector 8 is placed in the induction coil, eddy currents are induced within the fuel injector which generate precise amounts of localised heat without any physical contact between the induction coil and the fuel injector 8. As induction heating is highly directional, very small areas of the fuel injector 8 (i.e. the region of the interface of the ceiling end 22a of the accumulator volume 22 and the upper part of the encapsulated actuator arrangement 29a) can be heated without affecting the surrounding areas. Other types of sealing material may, of course, require different methods for the softening thereof if induction heating is not suitable.

Referring to FIG. 4c, in the next step of the method, a load P is applied to the base of the encapsulated actuator arrangement 29a in an axial direction so that the softened volume of sealing material 42 deforms and is urged into the spaces between the upper part of the encapsulated actuator arrangement 29a and the adjacent regions of both the accumulator volume 22 and the longitudinal drilling 48. In this manner, the shape of the sealing material 42 is deformed to substantially match that of the region of the interface of the accumulator volume ceiling end 22a and the upper part of the encapsulated actuator arrangement 29a. As can be seen in FIG. 4c, the sealing material is now disposed not only between the shoulder portion 44 of the second terminal member 36 and the ceiling end 22a of the accumulator volume 22, but also between the neck 46 of the second terminal member 36 and the wall of the longitudinal drilling 48 into which the upper portions of the first and second terminal members 34,36 extend. The axial load may be applied via a suitable tool, or a hydrostatic load may be applied by the application of a pressurised fluid.

In a second embodiment of the present invention, the sleeve member 30 is of a greater thickness in the region adjacent the shoulder portion 44 of the second terminal member 36 than in the other regions thereof. This region of greater thickness is referred to hereinafter as a volume of sealing material 42.

To form the seal member 38, heat is indirectly applied to the volume of sealing material 42 (i.e. the encapsulation material), and pressure is applied to the encapsulated actuator arrangement 29a in the same manner as described above. Alternatively, if the use of different materials to those described above is contemplated, different methods of indirectly heating the volume of sealing material 42 may be used.

In order to further improve the sealing function of the seal member 38, the ceiling end 22a of the accumulator volume 22, the longitudinal drilling 48 and the surface of the upper part of the encapsulated actuator arrangement 29a may be mechanically or chemically keyed to improve sealing between these components. This step would be carried out prior to the assembly of the fuel injector and the seal member 38 forming steps described above.

Having described particular preferred embodiments of the present invention, it is to be appreciated that the embodiments in question are exemplary only and that variations and modifications such as will occur to those possessed of the appropriate knowledge and skills may be made without departure from the scope of the invention as set forth in the appended claims. For example, it will be appreciated that the piezoelectric actuator arrangement need not include a stack of piezoelectric elements, but may include a single piezoelectric element.

The embodiments of the present invention do not include a pre-formed seal member. However, such a seal member may be utilised in addition to the seal 38 formed in accordance with the present invention. Thus, an additional volume of sealing material 42 could be applied to the encapsulated actuator arrangement and/or to the pre-formed seal member prior to the application of heat and pressure.

1. A method of assembling a fuel injector comprising a fuel injector body having an accumulator volume defined therein, the method comprising:
providing an encapsulated actuator arrangement having a piezoelectric actuator stack and electrical connector, wherein the stack is encapsulated in a sleeve member;
providing a volume of sealing material in the region of the electrical connector;
locating the encapsulated actuator arrangement in the accumulator volume;
applying heat indirectly to the volume of sealing material so as to soften the volume of sealing material; and
applying pressure to the encapsulated actuator arrangement such that the volume of sealing material deforms to form a substantially fluid-tight seal between the encapsulated actuator arrangement and the accumulator volume in the region of the electrical connector.

2. A method according to claim 1, wherein the locating step further comprises locating a pre-formed seal member between the encapsulated actuator arrangement and the accumulator volume in the region of the electrical connector.

3. A method according to claim 1, wherein the method comprises the further step of applying the volume of sealing material to the encapsulated actuator arrangement prior to the locating step.

4. A method according to claim 2, wherein the method comprises the further step of applying the volume of sealing material to the encapsulated actuator arrangement prior to the locating step.

5. A method according to claim 2, wherein the method comprises the further step of applying the volume of sealing material to the pre-formed seal member.

6. A method according to claim 4, wherein the method comprises the further step of applying an additional volume of sealing material to the pre-formed seal member.

7. A method according to claim 1, wherein the volume of sealing material is integrally formed with the sleeve member.

8. A method according to claim 1, wherein the electrical connector has a stepped profile defining a shoulder and a neck receivable by a passageway provided at a ceiling end of the accumulator volume, and wherein, during the step of applying pressure, the volume of sealing material deforms to form a substantially fluid-tight seal between at least a portion of the shoulder of the electrical connector and the ceiling end of the accumulator volume, and/or between at least a portion of the neck of the electrical connector and the passageway.

9. A method according to claim 1, wherein the method comprises the further step of preparing at least a portion of the accumulator volume and/or the encapsulated actuator arrangement so as to improve the adherence of the volume of sealing material thereto.

10. A method according to claim 9, wherein the preparing step comprises one or more of sandblasting, chemical etching, mechanical etching, cleaning, or applying a chemical adhesion promoter.

11. A method according to claim 1, wherein the volume of sealing material comprises an ultraviolet curable material.

12. A method according to claim 1, wherein the volume of sealing material comprises a thermoplastic material.

13. A method according to claim 12, wherein the thermoplastic material is one of the group comprising: poly ethyl ether ketone (PEEK), polyphenylene sulphide (PPS), liquid crystal polymer (LCP), and fluoropolymers.

14. A method according to claim 1, wherein heat is indirectly applied to the volume of sealing material via induction heating.

15. A method according to claim 1, wherein pressure is applied to the encapsulated actuator arrangement via hydrostatic loading.

16. A fuel injector produced according to the method of claim 1.
